(19) United States
(12) Patent Application Publication
(10) Pub. No.: US 2004/0078966 A1
(43) Pub. Date: Apr. 29, 2004

(54) Method of mounting electronic parts on wiring board

(75) Inventor: Atsunori Kajiki, Nagano-shi (JP)

Correspondence Address: STAAS & HALSEY LLP, SUITE 700, 1201 NEW YORK AVENUE, N.W., WASHINGTON, DC, 20005, US

(73) Assignee: SHINKO ELECTRIC INDUSTRIES CO., LTD., Nagano (JP)

(21) Appl. No.: 10/686,600

(22) Filed: Oct. 17, 2003

(30) Foreign Application Priority Data
Oct. 29, 2002 (JP) 2002-314275

(51) Int. Cl. H05K 3/34; H05K 3/30; H05K 3/00

(52) U.S. Cl. 29/840; 29/843; 29/832

(57) ABSTRACT

A method of mounting electronic parts, on a wiring board, is provided in which a bare chip is bonded to connecting pads via thin solder layers by means of flip chip bonding and at least another soldered part is soldered to a mounting pad on the board via a thin solder layer. First, adhesive resin layers are formed on the connecting pads and the mounting pad. Solder particles are scattered so that the solder particles temporarily adhere to the connecting pads and the mounting pad. The soldering part is put on the mounting pad and a reflow process is conducted so that the solder particles are made to reflow to pre-coat the connecting pads with a thin solder layer and, simultaneously, the soldered part is mounted on the mounting pad via solder. Finally, the bare chip is positioned on the thin solder layer of the connecting pads and a flip-chip bonding process is conducted by which the bare chip is flip-chip bonded to the connecting pads.

### BACKGROUND OF THE INVENTION

1. Field of the Invention

The present invention relates to a method of mounting electronic parts on a wiring board and, more particularly, to a method of mounting a bare chip and any other soldered parts (electronic parts to be mounted on a board by means of solder) on a wiring board.

2. Description of the Related Art

In the case where bare chips are bonded to a wiring board by means of flip chip bonding and any other electronic parts, except for the bare chips, such as IC devices (i.e. a package accommodating a semiconductor chip) resistors, condensers and the like are mounted on the wiring board by means of soldering, the following method has been conventionally used.

First of all, a thin solder layer is pre-coated on connecting pads for bonding the bare chips. These connecting pads for bonding are very small. For example, the size of one pad for bonding is 40 μm square. These very small pads for bonding are arranged at a very fine pitch such as 100 μm and formed into a predetermined pattern. Therefore, it is impossible to form a thin solder layer on the above very fine pad pattern by a conventional method of coating solder paste.

Therefore, as a method of pre-coating a thin solder layer on the above very fine pad pattern, a method called the “Super Jufit Method” has been developed. For example, refer to Japanese Patent No. 2592757 (JP-A-7-7244).

According to this method, an adhesive resin layer made of predetermined material is formed on pads used for bonding. Next, solder particles are scattered and made to temporarily adhere to the pads for bonding by the adhesive resin layer. Then, the solder particles are made to reflow, so that a thin solder layer is pre-coated. When solder particles, the particles sizes of which are small, are used, it is possible to form a thin solder layer even on the above very fine pad pattern.

On the pads for mounting on which parts to be soldered (electronic parts except for the bare chips which are bonded by means of flip chip bonding) are mounted after a thin solder layer has been coated, by the conventional method of screen printing, solder paste into which flux is mixed is coated and the parts to be soldered are put on the pads. Then, the pads are heated in a furnace for reflowing so as to reflow the solder particles contained in the paste. In this way, the parts to be soldered are bonded by means of soldering.

Solder particles contained in the solder paste are made of, for example, a eutectic solder of tin-lead, the fusing point of which is relatively low. On the other hand, solder particles scattered on the pads for bonding are made of, for example, a tin-silver alloy, the fusing point of which is higher than that of the solder particles contained in the paste.

After cleaning has been conducted so as to remove the flux, bare chips are positioned on the pads for bonding on which the thin solder layer is pre-coated, and heated by an exclusively used flip chip bonder, so that the bare chips can be bonded by means of flip chip bonding.

However, the above electronic parts mounting method has the following disadvantages.

Solder paste coated on the pads for mounting contains flux and the other resin components. When they are heated in a reflow furnace, a portion of the flux and the other resin components are changed into gas. Thus formed impurities attach to a thin solder layer (pre-coating layer) on the pads for bonding, which is previously formed, and form a film.

Accordingly, it is necessary to provide a cleaning process for removing these impurities, which is inconvenient. Further, the cleaning unit must be added to the apparatus, and the time and the equipment necessary for cleaning are required. Furthermore, chemicals such as a detergent and a substitute agent necessary for cleaning the super fine portion are required and special equipment must be provided, which increases the manufacturing cost.

In the case of an organic board, the board is attacked by the residue, that is, there is a high possibility that the board is damaged. For the above reasons, when cleaning is executed, the reliability of the board is deteriorated.

### SUMMARY OF THE INVENTION

The present invention has been accomplished to solve the above problems of the prior art.

It is an object of the present invention to provide a method of mounting electronic parts on a wiring board characterized in that the time and the number of processes can be reduced and the cost can be reduced.

In order to solve the above problems, according to the present invention, there is provided a method of mounting electronic parts on a wiring board in which a bare chip is bonded to connecting pads via thin solder layers by means of flip chip bonding and at least another soldered part is soldered to a mounting pad on the board via a thin solder layer, said method comprising the following steps of: a step of forming adhesive resin layers on the connecting pads and the mounting pad; a step of scattering solder particles so that the solder particles temporarily adhere to the connecting pads and the mounting pad; a step of putting the soldering part on the mounting pad and reflowing so that the solder particles are made to reflow to pre-coat the connecting pads with a thin solder layer and simultaneously the soldering part is mounted on the mounting pad via solder; and a step of putting the bare chip to be positioned on the thin solder layer of the connecting pads and flip-chip bonding by which the bare chip is flip-chip bonded to the connecting pads.

The adhesive resin layers are formed on the connecting pads and the mounting pad by dipping the board in a solution of a tackifier chemical compound.

Otherwise, the adhesive resin layers are formed by coating the connecting pads and the mounting pad with a solution of a tackifier chemical compound.

It is advantageous that the solder particles are made of tin-silver alloy.

### BRIEF DESCRIPTION OF THE DRAWINGS

FIG. 1 is a schematic illustration of a wiring board;

FIG. 2 is a schematic illustration showing a state in which solder particles are temporarily bonded and includes enlarged views of the connecting pad and the mounting pad;

FIG. 3 is a schematic illustration showing a state in which a thin solder layer is pre-coated and soldering parts are simultaneously mounted and includes an enlarged view of the connecting pad; and

FIG. 4 is a schematic illustration showing a state in which a bare chip is bonded by means of flip chip bonding.

### DETAILED DESCRIPTION OF THE PREFERRED EMBODIMENTS

Referring to the accompanying drawings, a preferred embodiment of the present invention will be explained in detail as follows.

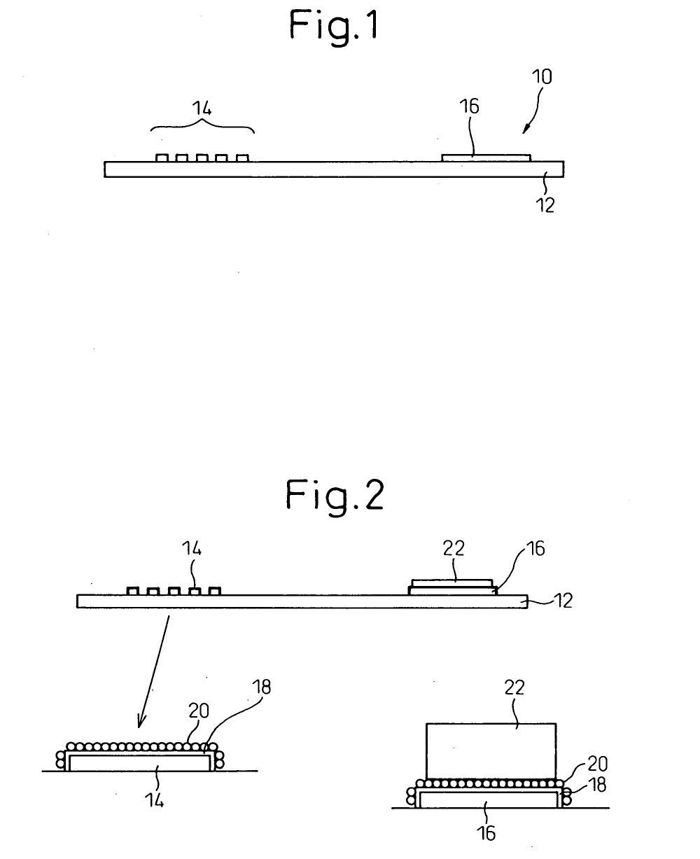

FIG. 1 is a schematic illustration showing a model of the wiring board 10. The wiring board 10 is composed of multiple layers. On the surface layer of the board 12, on which electronic parts are to be mounted, there are provided connecting pads 14, for bonding, on which bare chips are to be mounted, and there are also provided pads 16, for mounting, on which soldering parts such as IC devices, resistors, condensers and the like are to be mounted. These pads 14 and 16 are formed and exposed.

According to the present invention, the thin solder layer is formed on the pads 14 for bonding and the pads 16 for mounting all at once by the “Super Jufit Method”.

When, the board 12 is dipped in the solution of tackifier chemical compound shown in the above Japanese Patent No. 2592757 or when the board 12 is coated with the solution of the tackifier chemical compound, it is possible to form an adhesive resin layer 18 (FIG. 2) on the pads 14 for bonding and the pads 16 for mounting which are metallic exposure portions. Examples of the tackifier chemical compound disclosed in Japanese Patent No. 2592757 are naphttriazole derivative, benzotriazole derivative, imidazole derivative, benzoimidazole derivative, and mercaptobenzothiazole derivative therefore, in this invention, at least one of these tackifier chemical compounds can be used.

Next, as shown in FIG. 2, the solder particles 20, the diameters of which are small, made of tin-silver alloy are scattered, and the thus scattered solder particles 20 are made to temporarily adhere to the pads 14 for bonding and the pads 16 for mounting by the aforementioned adhesive resin layer 18.

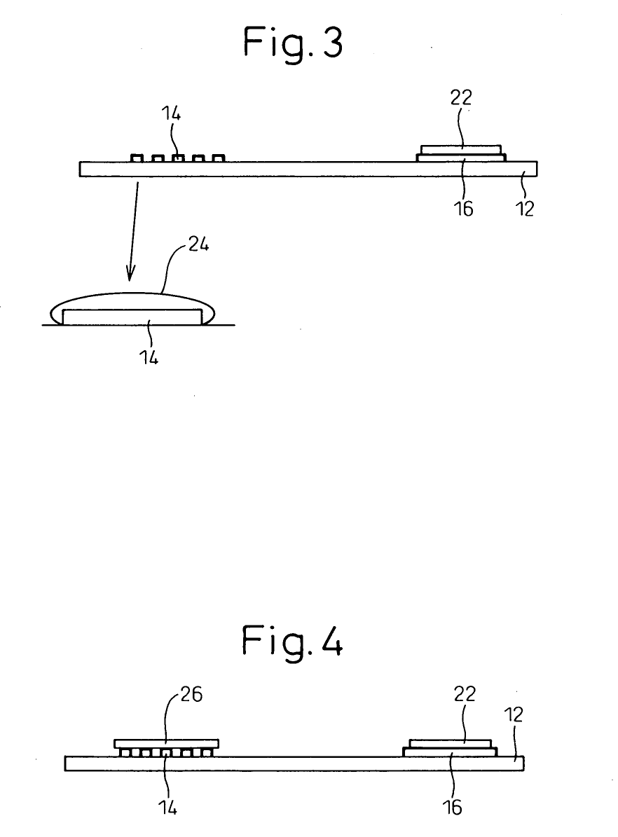

Next, the soldering parts 22 are put on the pads 16 for mounting and accommodated in a furnace (not shown) so as to reflow the solder particles 20 and pre-coat the thin solder layer 24 (FIG. 4) on the pads 14 for bonding. In this way, the soldering parts 22 are mounted on the pads 16 for mounting via fused solder (shown in FIG. 3).

Next, as shown in FIG. 4, the bare chips 26 are positioned and put on the thin solder layer 24 of the pads 14 for bonding, and the bare chips 26 are heated with a chip bonder (not shown), so that the bare chips 26 are bonded to the pads 14 for bonding by means of flip chip bonding. In this way, it is possible to provide a wiring board 10 on which various electronic parts are mounted on the board 12.

According to the above process, as no flux is used, it is unnecessary to provide a cleaning process for removing solder flux.

It is possible to conduct a pre-coating process of the thin solder layer 24 on the pads 14 for bonding and a reflow process for mounting soldering parts in the same process. Accordingly, it is possible to reduce the time required. Further, it is possible to reduce the number of processes. As a result, the cost can be reduced.

In this connection, in the case of pre-coating of the thin solder layer, it is possible to adopt the “Super Solder Method” instead of the aforementioned the “Super Jufit Method”.

As described above, according to the present invention, in the process in which a thin solder layer is pre-coated on the pads for flip chip bonding, it is possible to simultaneously mount the soldering parts. Therefore, it is possible to reduce the number of processes necessary for mounting the soldering parts. Accordingly, time can be saved.

As no solder flux is used, it is possible to omit the flux cleaning process.

Further, as it is possible to omit a process of mounting the soldering parts in a heating furnace between the process of pre-coating the thin solder layer and the process of flip chip bonding, it is possible to prevent another substance from attaching to and mixing with the thin solder layer that has been pre-coated.

Due to the saving of time, thermal hysteresis given to the board is decreased, and the reliability can be greatly enhanced.

It should be understood by those skilled in the art that the foregoing description relates to only a preferred embodiment of the disclosed invention, and that various changes and modifications may be made to the invention without departing the sprit and scope thereof.

1. A method of mounting electronic parts, on a wiring board, in which a bare chip is bonded to connecting pads via thin solder layers by means of flip-chip bonding and at least another soldered part is soldered to a mounting pad on the board via a thin solder layer, said method comprising the following steps of:
a step of forming adhesive resin layers on the connecting pads and the mounting pad;
a step of scattering solder particles so that the solder particles temporarily adhere to the connecting pads and the mounting pad;
a step of putting the soldered part on the mounting pad and reflowing so that the solder particles are made to reflow to pre-coat the connecting pads with a thin solder layer and simultaneously the soldered part is mounted on the mounting pad via solder; and
a step of putting the bare chip to be positioned on the thin solder layer of the connecting pads and flip-chip bonding by which the bare chip is flip-chip bonded to the connecting pads.

2. A method as set forth in claim 1, wherein the adhesive resin layers are formed on the connecting pads and the mounting pad by dipping the board in a solution of a tackifier chemical compound.

3. A method as set forth in claim 1, wherein the adhesive resin layers are formed by coating the connecting pads and the mounting pad with a solution of a tackifier chemical compound.

4. A method as set forth in claim 1, wherein the solder particles are made of tin-silver alloy.
